(19) United States
(12) Patent Application Publication
(10) Pub. No.: US 2010/0301467 A1
(43) Pub. Date: Dec. 2, 2010

(54) WIREBOND STRUCTURES

(76) Inventor: Albert Wu, Palo Alto, CA (US)

Correspondence Address: SCHWABE, WILLIAMSON & WYATT, P.C., PACWEST CENTER, SUITE 1900, 1211 S.W. FIFTH AVENUE, PORTLAND, OR, 97204, US

(21) Appl. No.: 12/786,260

(22) Filed: May 24, 2010

Related U.S. Application Data
(60) Provisional application No. 61/181,141, filed on May 26, 2009.

(51) Int. Cl. H01L 23/49; H01L 23/31; H01L 21/60

(52) U.S. Cl. 257/692; 257/784; 438/612; 257/E23.024; 257/E21.509; 257/E23.124

(57) ABSTRACT

Embodiments of the present disclosure provide an apparatus comprising a semiconductor die, a bond pad formed on the semiconductor die, the bond pad comprising aluminum (Al), a bonding material comprising gold (Au) coupled to the bond pad, the bonding material covering at least a portion of the bond pad, and a wire coupled to the bonding material, the wire comprising copper (Cu). Other embodiments may be described and/or claimed.

### CROSS REFERENCE TO RELATED APPLICATIONS

The present application claims priority to U.S. Provisional Patent Application No. 61/181,141, filed May 26, 2009, the entire specification of which is hereby incorporated by reference in its entirety for all purposes, except for those sections, if any, that are inconsistent with this specification.

### TECHNICAL FIELD

Embodiments of the present disclosure relate to the field of integrated circuits, and more particularly, to wirebond structures, and associated fabrication processes.

### BACKGROUND

Copper wires are an emerging technology for wirebonding applications in the fabrication/assembly of integrated circuits. Copper wires do not form a reliable direct bond with some materials such as, for example, aluminum. A wirebond formed directly between a copper wire and an aluminum material, for example, may fail due to poor adhesion of the materials under various reliability tests such as temperature, humidity, and/or bias tests.

The description in this section is related art, and does not necessarily include information disclosed under 37 C.F.R. 1.97 and 37 C.F.R. 1.98. Unless specifically denoted as prior art, it is not admitted that any description of related art is prior art.

### SUMMARY

The present disclosure provides an apparatus comprising a semiconductor die, a bond pad formed on the semiconductor die, the bond pad comprising aluminum (Al), a bonding material comprising gold (Au) coupled to the bond pad, the bonding material covering at least a portion of the bond pad, and a wire coupled to the bonding material, the wire comprising copper (Cu).

In various embodiments, the bonding material is a film formed on the bond pad.

In various embodiments, a passivation layer is formed on the semiconductor die, the passivation layer being positioned to cover at least a portion of the bond pad.

The present disclosure further provides a method comprising forming a bond pad on a semiconductor die, the bond pad comprising aluminum (Al), depositing a bonding material comprising gold (Au) to cover at least a portion of the bond pad, and bonding a wire to the bonding material, the wire comprising copper (Cu).

In various embodiments, depositing the bonding material is performed to form a film on the bond pad.

In various embodiments, the method further includes singulating the semiconductor die, wherein depositing the bonding material to form a film is performed prior to singulating the semiconductor die.

The present disclosure further provides a semiconductor package comprising a semiconductor die, a bond pad formed on the semiconductor die, the bond pad comprising aluminum (Al), a bonding material comprising gold (Au) coupled to the bond pad, the bonding material covering at least a portion of the bond pad, a wire coupled to the bonding material, the wire comprising copper (Cu), and a package substrate electrically coupled to the semiconductor die via the wire.

In various embodiments, a passivation layer is formed on the semiconductor die, the passivation layer being positioned to cover at least a portion of the bond pad.

In various embodiments, a mold compound is formed to encapsulate the semiconductor die and the wire.

### BRIEF DESCRIPTION OF THE DRAWINGS

Embodiments of the present disclosure will be readily understood by the following detailed description in conjunction with the accompanying drawings. To facilitate this description, like reference numerals designate like structural elements. Embodiments herein are illustrated by way of example and not by way of limitation in the figures of the accompanying drawings.

FIG. 1 schematically illustrates a semiconductor package, in accordance with various embodiments.

FIG. 2 schematically illustrates a wirebond structure, in accordance with various embodiments.

FIG. 3 schematically illustrates another wirebond structure, in accordance with various embodiments.

FIG. 4 is a process flow diagram of a method to fabricate a semiconductor package having a wirebond structure, in accordance with various embodiments.

FIG. 5 is a process flow diagram of another method to fabricate a semiconductor package having a wirebond structure, in accordance with various embodiments.

FIG. 6 is a process flow diagram of yet another method to fabricate a semiconductor package having a wirebond structure, in accordance with various embodiments.

### DETAILED DESCRIPTION

Embodiments of the present disclosure describe wirebond structures and associated techniques and configurations. In the following detailed description, reference is made to the accompanying drawings which form a part hereof, wherein like numerals designate like parts throughout. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

The description may use perspective-based descriptions such as up/down, back/front, over/under, above/beneath, underlying, and top/bottom. Such descriptions are merely used to facilitate the discussion and are not intended to restrict the application of embodiments described herein to any particular orientation.

For the purposes of the present disclosure, the phrase “A/B” means A or B. For the purposes of the present disclosure, the phrase “A and/or B” means “(A), (B), or (A and B).” For the purposes of the present disclosure, the phrase “at least one of A, B, and C” means “(A), (B), (C), (A and B), (A and C), (B and C), or (A, B and C).” For the purposes of the present disclosure, the phrase “(A)B” means “(B) or (AB)” that is, A is an optional element.

Various operations are described as multiple discrete operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The description uses the phrases “in an embodiment,” “in embodiments,” or similar language, which may each refer to one or more of the same or different embodiments. Furthermore, the terms “comprising,” “including,” “having,” and the like, as used with respect to embodiments of the present disclosure, are synonymous.

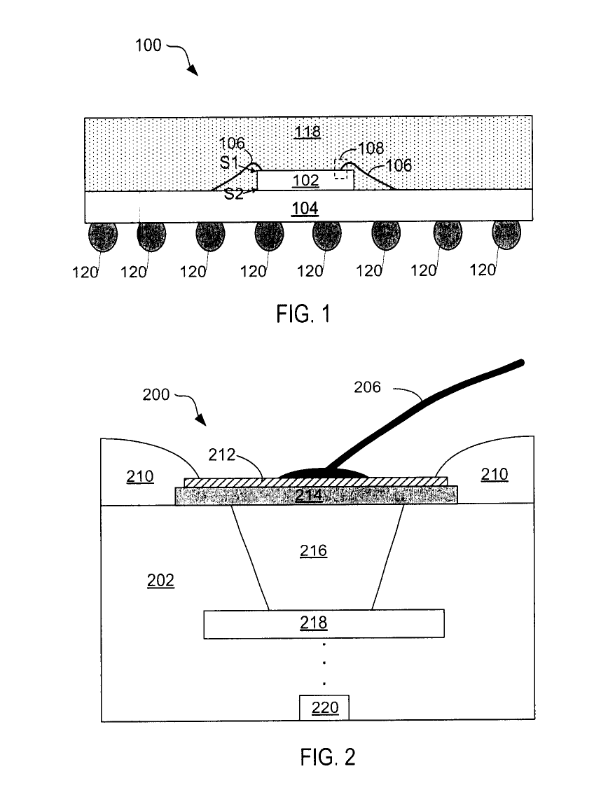

FIG. 1 schematically illustrates a semiconductor package 100, in accordance with various embodiments. The semiconductor package 100 includes a semiconductor die 102 and package substrate 104, coupled as shown. An adhesive (not shown) such as epoxy or silver paste is generally used to physically attach the semiconductor die 102 to the package substrate 104.

The semiconductor die 102 can include any of a wide variety of integrated circuit devices (not shown). The integrated circuit devices are generally formed on a surface of a semiconductor substrate referred to as an “active” side (e.g., S1 of the semiconductor die 102), which is opposite to an “inactive” side (e.g., S2 of the semiconductor die 102). For example, the semiconductor die 102 may include transistors or memory cells formed on an active side (e.g., S1) of the semiconductor die 102. The semiconductor die 102 may function, for example, as a processor or memory. The semiconductor die 102 is not limited to these devices and may include other devices in other embodiments. In an embodiment, the semiconductor die 102 comprises silicon.

The package substrate 104 represents a wide variety of package substrates. For example, the package substrate 104 may be a leadframe, printed circuit board, or flex circuit. The package substrate 104 is not limited to these types of substrates and may include other suitable package substrates in other embodiments.

One or more wires 106 electrically couple the semiconductor die 102 with the package substrate 104 to provide an electrical pathway to and/or from various components of the semiconductor die 102. For example, the one or more wires 106 can be used to provide input/output (I/O) signals or power for the semiconductor die 102. The one or more wires 106 are generally bonded to bond pads, leads, or traces of the semiconductor die 102 and further bonded to corresponding bond pads, leads, or traces of the package substrate 104.

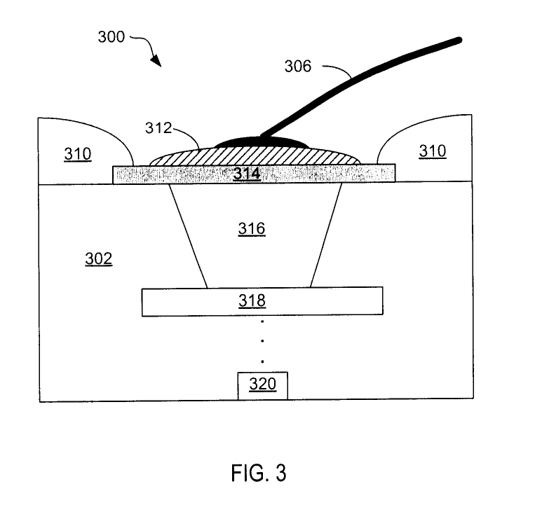

Region 108 indicates an example area where a wirebond structure (e.g., 200 of FIG. 2 or 300 of FIG. 3) is formed between the one or more wires 106 and a surface of the semiconductor die 102. A wirebond structure formed in the region 108 is described in greater detail in connection with the wirebond structures 200 of FIGS. 2 and 300 of FIG. 3. According to various embodiments, the one or more wires 106 comprise copper including, for example, copper alloys.

A mold compound 118 such as an epoxy-based material is formed to encapsulate the semiconductor die 102, as illustrated. The mold compound 118 protects the semiconductor die 102 from defects associated with moisture and oxidation and provides a stronger, more robust flex circuit package 100 by encapsulating and holding the semiconductor die 102 to the package substrate 104. The mold compound 118 generally includes polymers such as epoxy resins, but materials for the mold compound 118 are not limited in this regard. Other suitable electrically insulative materials can be used to form a mold compound 118 in other embodiments.

One or more structures (e.g., solder balls 120) may be used to further electrically couple the package substrate 104 with other electronic devices such as a motherboard (not shown) or other type of circuit board. Other types of structures to electrically couple the package substrate 104 with other electronic devices can be used in other embodiments.

Embodiments described herein may include wirebonding configurations other than the configuration depicted for semiconductor package 100. For example, multiple semiconductor dies may be coupled to the package substrate 104 or stacked on one another in other configurations.

FIG. 2 schematically illustrates a wirebond structure 200, in accordance with various embodiments. The wirebond structure 200 includes a bond pad 214 formed on a surface (e.g., S1 of FIG. 1) of a semiconductor die 202. The bond pad 214 is electrically coupled to one or more integrated circuit devices 220, such as transistors, through one or more interconnect structures (e.g., 216 and 218). The one or more interconnect structures may include, for example, alternating layers of a via-type structure 216 and metal line 218 formed to provide an electrical connection between the one or more integrated circuit devices 220 of the semiconductor die 202 and the bond pad 214.

The bond pad 214 is formed by depositing an electrically conductive material to a surface of the semiconductor die 202. In an embodiment, the bond pad 214 comprises aluminum (Al). The electrically conductive material can be deposited using a variety of deposition techniques including, for example, electroplating, physical vapor deposition (PVD), chemical vapor deposition (CVD), and/or atomic layer deposition (ALD). Other deposition techniques may be used to form the bond pad 214 in other embodiments.

The bond pad 214 is generally formed during a die fabrication process associated with fabricating the semiconductor die (e.g., 102 of FIG. 1). The die fabrication process includes various deposition and patterning operations to form integrated circuit devices 220 and interconnect structures (e.g., 216 and 218) on a semiconductor wafer (not shown). The semiconductor wafer generally includes multiple semiconductor dies formed thereon.

A passivation layer 210 is formed to provide a protective coating on a surface (e.g., S1 of FIG. 1) of the semiconductor die 202. For example, an electrically insulative material used to form the passivation layer 210 is deposited to substantially cover the surface of the semiconductor die 202. Portions of the passivation layer 210 are selectively removed to provide openings in the passivation layer 210 over bond pads (e.g., bond pad 214) formed on the semiconductor die 202 to allow attachment of one or more wires (e.g., wire 206) to the bond pads. In an embodiment, the passivation layer 210 is positioned to cover at least a portion of the bond pad 214, as illustrated. The passivation layer 210 may include a variety of electrically insulative materials such as a polymer, oxide, or nitride material. Other electrically insulative materials may be used in other embodiments.

A bonding material 212 is formed on the bonding pad 214 to facilitate bonding between the bond pad 214 and a wire 206. The wire comprises an electrically conductive material such as copper (Cu). According to various embodiments, the bonding material 212 is an electrically conductive material comprising gold (Au). In other embodiments, the bonding material 212 comprises palladium, nickel, or other metals. In an embodiment, the bonding material 212 comprising gold is deposited to form a film on the bond pad 214 comprising aluminum. The bonding material 212 made of gold provides a more reliable bond between a copper wire and an aluminum bond pad than a direct bond between the copper wire and the aluminum bond pad.

In an embodiment, the bonding material 212 is a film formed to substantially cover the bond pad 214, as illustrated. The bonding material 212 generally has a substantially uniform thickness. The bonding material 212 can be deposited according to a variety of techniques including electroplating, physical vapor deposition (PVD), chemical vapor deposition (CVD), and/or atomic layer deposition (ALD). Other deposition techniques may be used to form the bonding material 212 in other embodiments.

In an embodiment, the bonding material 212 is deposited prior to deposition of the passivation layer 210. For example, the bonding material 212 can be deposited during a die fabrication process associated with fabricating the semiconductor die (e.g., 102 of FIG. 1), prior to singulation of the semiconductor die from a semiconductor wafer. In an embodiment, the passivation layer 210 at least partially covers or overlaps the bonding material 212 and the bond pad 214, as shown.

The wire 206 is bonded to the bonding material 212 on the bond pad 214 to form the wirebond structure 200. The wire 206 can be used to electrically couple the one or more integrated circuit devices 220 of the semiconductor die 202 with electronic devices external to the semiconductor die 202, such as a package substrate (e.g., package substrate 104). The wire 206 can be bonded to the bonding material 212 using a variety of wirebonding processes including, for example, ball bonding or wedge bonding. Other wirebonding techniques can be used in other embodiments. The wire 206 is generally bonded subsequent to singulation of the semiconductor die (e.g., 102 of FIG. 1) during an assembly process to fabricate a semiconductor package (e.g., 100).

FIG. 3 schematically illustrates another wirebond structure 300, in accordance with various embodiments. A bond pad 314 is formed on a surface of semiconductor die 302, as illustrated.

A bonding material 312 is formed on the bond pad 314 to facilitate bonding with a wire 306. According to various embodiments, the bonding material 312 comprises gold to facilitate bonding between the bond pad 314 comprising aluminum and the wire 306 comprising copper. In an embodiment, the bonding material 312 is formed using a spherical structure comprising gold such as a gold ball. For example, the bonding material 312 can be formed using any suitable gold ball bonding or other bump-producing technique to form a bond between the gold ball and the aluminum bond pad 314. Ball bonding techniques generally provide the bonding material 312 that has an amorphous or spherical shape such as a bump, as illustrated. For example, the bonding material 312 may have a substantially non-uniform thickness when formed using a gold ball.

According to various embodiments, the bonding material 312 is deposited during an assembly process, e.g., subsequent to singulation of the semiconductor die (e.g., 102 of FIG. 1). The assembly process generally includes operations associated with die singulation, die attachment to a package substrate, wirebonding, and/or molding. In an embodiment, the bonding material 312 serves as a buffer structure to protect the semiconductor die 302 from heat associated with a wirebonding process that is used to electrically couple the wire 306 to the bond pad 314.

The wire 306 is bonded to the bonding material 312 to form the wirebond structure 300. A passivation layer 310 is formed to protect the semiconductor die 302. According to various embodiments, the passivation layer 310 is deposited prior to depositing the bonding material 312. The passivation layer 310 may partially overlap at least a portion of the bond pad 314, as illustrated.

The semiconductor die 302 generally includes one or more integrated circuit devices 320 electrically coupled to the bond pad 314 through one or more interconnect structures (e.g., 316 and 318). In various embodiments, the wirebond structure 300 of FIG. 3 includes features that comport with embodiments described for similar features of FIG. 2. For example, the one or more integrated circuit devices 320, the one or more interconnect structures (e.g., 316 and 318), the semiconductor die 302, the bond pad 314, the passivation layer 310, and the wire 306 may comport with embodiments described for respective features (e.g., 220, 216, 218, 202, 214, 210, and 206) of FIG. 2.

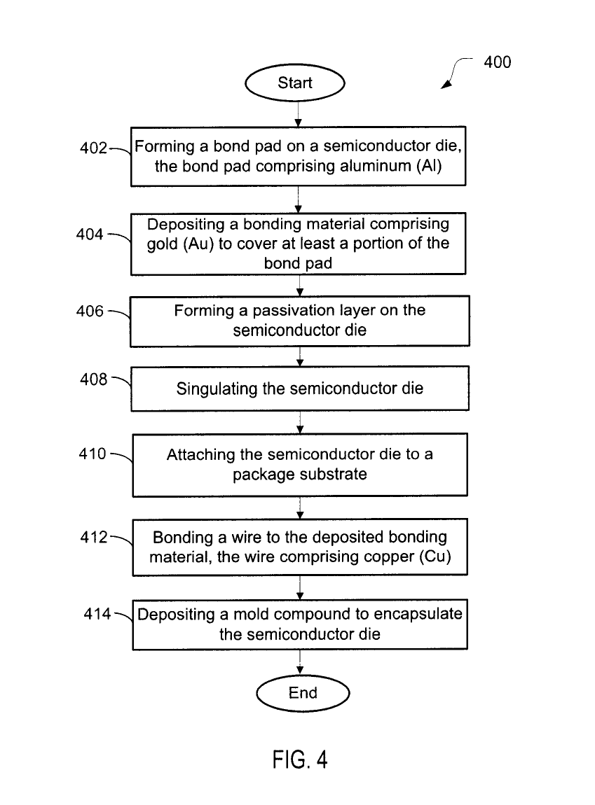

FIG. 4 is a process flow diagram of a method 400 to fabricate a semiconductor package (e.g., 100 of FIG. 1) having a wirebond structure (e.g., 200 of FIG. 2), in accordance with various embodiments. At 402, the method 400 includes forming a bond pad (e.g., 214 of FIG. 2) on a semiconductor die (e.g., 102 of FIG. 1), the bond pad comprising aluminum (Al). The bond pad is formed, for example, by depositing an electrically conductive material on a surface (e.g., S1 of FIG. 1) of the semiconductor die. Patterning processes such as lithography and/or etch processes can be used to provide a desired pattern on the surface of the semiconductor die to facilitate selective deposition of the bond pad material. The bond pad may be electrically coupled to one or more underlying interconnect structures such as via structures or metal lines.

At 404, the method 400 further includes depositing a bonding material (e.g., 212 of FIG. 2) comprising gold (Au) to cover at least a portion of the bond pad. In an embodiment, the bonding material is deposited to form a thin film on the bond pad having a substantially uniform thickness. The bonding material can be deposited according to a variety of techniques including electroplating, physical vapor deposition (PVD), chemical vapor deposition (CVD), and/or atomic layer deposition (ALD). Other deposition techniques can be used to deposit the bonding material in other embodiments. According to various embodiments, the bonding material is deposited prior to forming a passivation layer on the semiconductor die (e.g., at 406) and/or prior to singulating the semiconductor die (e.g., at 408).

At 406, the method 400 further includes forming a passivation layer (e.g., 210 of FIG. 2) on the semiconductor die. The passivation layer can be deposited by a variety of techniques. For example, an electrically insulative material can be spun on a wafer hosting the semiconductor die to provide a coating of substantially uniform thickness on the semiconductor die. The passivation layer can include a variety of materials including, for example, polymer, oxide, or nitride materials. The passivation layer is generally patterned to provide openings over the bond pads to allow coupling of wires to the bond pads. In an embodiment, the passivation layer is formed to at least partially cover or overlap the bonding material formed on the bond pad. Other materials and/or deposition techniques for a passivation layer can be used in other embodiments.

At 408, the method 400 further includes singulating the semiconductor die. In a case where a plurality of semiconductor dies are formed, e.g., on a wafer substrate, the wafer substrate is cut or otherwise singulated to provide discrete semiconductor dies for packaging/assembly. Singulating the semiconductor die can be performed using, for example, lasers or saws, but is not limited to these techniques.

At 410, the method 400 further includes attaching the semiconductor die (e.g., 102 of FIG. 1) to a package substrate (e.g., 104 of FIG. 1). The semiconductor die can be attached using a variety of techniques or materials. An adhesive such as epoxy or silver paste, for example, can be used to attach a surface (e.g., S2 of FIG. 1) of the semiconductor die to the package substrate. Other techniques and/or materials can be used to attach the semiconductor die in other embodiments.

At 412, the method 400 further includes bonding a wire (e.g., 206 of FIG. 2) to the deposited bonding material, the wire comprising copper (Cu). The wire can be bonded to the bonding material using any suitable wirebonding technique including, for example, ball bonding or wedge-bonding. Nitrogen can be used to provide an environment that reduces or prevents the formation of oxides that potentially form during wirebonding with a copper material. A bond or weld is generally formed between the wire and the bonding material by application of heat, pressure, and/or ultrasonic energy. A bond or weld may further be formed between the wire and the package substrate according to similar techniques.

At 414, the method 400 further includes depositing a mold compound (e.g., 118 of FIG. 1) to encapsulate the semiconductor die. The mold compound can be deposited by any suitable technique to substantially cover exposed areas of the semiconductor die (e.g., 102 of FIG. 1) and to adhere to a surface of the package substrate (e.g., 104 of FIG. 1). The mold compound generally includes polymers such as epoxy, but is not limited in this regard. Other materials for a mold compound can be used in other embodiments.

Generally, operations associated with blocks 402, 404, and 406 are performed during a die fabrication process to fabricate the semiconductor die and operations associated with blocks 408, 410, 412, and 414 are performed during an assembly process to form a semiconductor package using the semiconductor die. Subject matter is not limited in this regard, and the operations and/or actions of method 400 may be performed at other times according to a process flow for a semiconductor die.

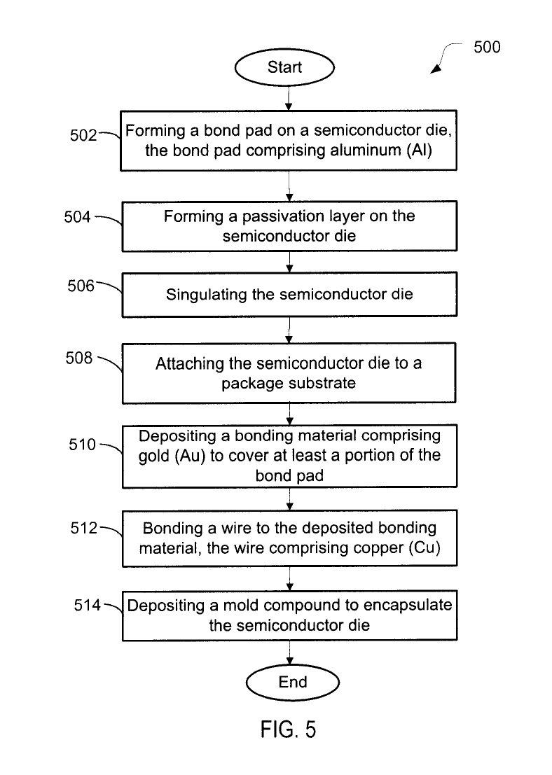

FIG. 5 is a process flow diagram of another method 500 to fabricate a semiconductor package (e.g., 100 of FIG. 1) having a wirebond structure (e.g., 300 of FIG. 3), in accordance with various embodiments. At 502, the method 500 includes forming a bond pad (e.g., 314 of FIG. 3) on a semiconductor die (e.g., 302 of FIG. 3), the bond pad comprising aluminum (Al).

At 504, the method 500 further includes forming a passivation layer (e.g., 310 of FIG. 3) on the semiconductor die. The passivation layer is formed to cover at least a portion of the bond pad. At 506, the method 500 further includes singulating the semiconductor die.

At 508, the method 500 further includes attaching the semiconductor die (e.g., 102 of FIG. 1) to a package substrate (e.g., 104 of FIG. 1). The semiconductor die can be attached using any suitable technique including using epoxy or silver paste as an adhesive to physically attach the die to the package substrate.

At 510, the method 500 further includes depositing a bonding material (e.g., 312 of FIG. 3) comprising gold (Au) to cover at least a portion of the bond pad. According to various embodiments, the bonding material is deposited as a spherical gold ball on the bond pad. For example, the bonding material can be deposited using a ball bonding technique to form a bump of gold material on the bond pad. According to various embodiments, the bonding material is formed by depositing a gold ball subsequent to singulation of the semiconductor die (e.g., at 506) or subsequent to attaching the semiconductor die to the package substrate (e.g., at 508). In another embodiment, the bonding material is deposited subsequent to forming the passivation layer (e.g., at 504).

At 512, the method 500 further includes bonding a wire (e.g., 306 of FIG. 3) to the deposited bonding material, the wire comprising copper (Cu). In an embodiment, the deposited bonding material is a buffer structure that protects the semiconductor die from heat associated with bonding the wire to the bonding material (e.g., at 512).

At 514, the method 500 further includes depositing a mold compound (e.g., 118 of FIG. 1) to encapsulate the semiconductor die. The mold compound can be deposited using any suitable deposition technique.

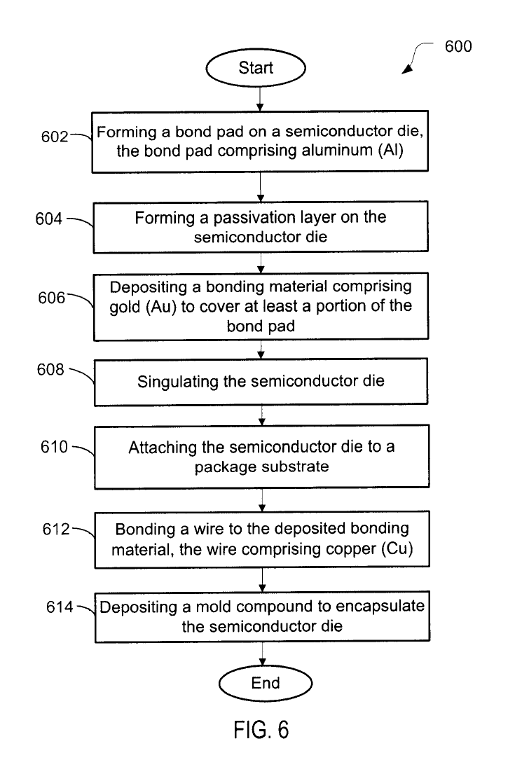

FIG. 6 is a process flow diagram of yet another method 600 to fabricate a semiconductor package having a wirebond structure, in accordance with various embodiments. At 602, the method 600 includes forming a bond pad (e.g., 314 of FIG. 3) on a semiconductor die (e.g., 302 of FIG. 3), the bond pad comprising aluminum (Al).

At 604, the method 600 further includes forming a passivation layer (e.g., 310 of FIG. 3) on the semiconductor die. The passivation layer is formed to cover at least a portion of the bond pad.

At 606, the method 600 further includes depositing a bonding material (e.g., 312 of FIG. 3) comprising gold (Au) to cover at least a portion of the bond pad. According to various embodiments, the bonding material is deposited as a spherical gold ball on the bond pad. For example, the bonding material can be deposited using a ball bonding technique to form a bump of gold material on the bond pad. In an embodiment, the bonding material is formed by depositing a gold ball prior to singulation of the semiconductor die (e.g., at 608). For example, the semiconductor die may still be part of a wafer. In another embodiment, the bonding material is deposited subsequent to forming the passivation layer (e.g., at 604).

At 608, the method 600 further includes singulating the semiconductor die. The die can be singulated using any suitable technique including, for example, sawing or laser-cutting.

At 610, the method 600 further includes attaching the semiconductor die (e.g., 102 of FIG. 1) to a package substrate (e.g., 104 of FIG. 1). The semiconductor die can be attached using any suitable technique including using epoxy or silver paste as an adhesive to physically attach the die to the package substrate.

At 612, the method 600 further includes bonding a wire (e.g., 306 of FIG. 3) to the deposited bonding material, the wire comprising copper (Cu). In an embodiment, the deposited bonding material is a buffer structure that protects the semiconductor die from heat associated with bonding the wire to the deposited bonding material (e.g., at 612).

At 614, the method 600 further includes depositing a mold compound (e.g., 118 of FIG. 1) to encapsulate the semiconductor die. The mold compound can be deposited using any suitable deposition technique. Operations described in connection with methods 500 and 600 may comport with embodiments described in connection with method 400.

Although certain embodiments have been illustrated and described herein, a wide variety of alternate and/or equivalent embodiments or implementations calculated to achieve the same purposes may be substituted for the embodiments illustrated and described without departing from the scope of the present disclosure. This disclosure is intended to cover any adaptations or variations of the embodiments discussed herein. Therefore, it is manifestly intended that embodiments described herein be limited only by the claims and the equivalents thereof.

What is claimed is:

1. An apparatus comprising:
a semiconductor die;
a bond pad formed on the semiconductor die, the bond pad comprising aluminum (Al);
a bonding material comprising gold (Au) coupled to the bond pad, the bonding material covering at least a portion of the bond pad; and
a wire coupled to the bonding material, the wire comprising copper (Cu).

2. The apparatus of claim 1, wherein the bonding material is a film formed on the bond pad.

3. The apparatus of claim 2, wherein the bonding material is coupled to the bond pad prior to singulation of the semiconductor die.

4. The apparatus of claim 2, wherein the film is at least partially covered by a passivation layer formed over the semiconductor die.

5. The apparatus of claim 2, wherein the film has a substantially uniform thickness.

6. The apparatus of claim 1, wherein the bonding material is formed using a spherical gold ball.

7. The apparatus of claim 6, wherein the bonding material is coupled to the bond pad subsequent to singulation of the semiconductor die.

8. The apparatus of claim 1, further comprising:
a passivation layer formed on the semiconductor die, the passivation layer being positioned to cover at least a portion of the bond pad.

9. The apparatus of claim 1, wherein the bonding material protects the semiconductor die from heat associated with a wirebonding process that is used to electrically couple the wire to the bond pad.

10. A method comprising:
forming a bond pad on a semiconductor die, the bond pad comprising aluminum (Al);
depositing a bonding material comprising gold (Au) to cover at least a portion of the bond pad; and
bonding a wire to the bonding material, the wire comprising copper (Cu).

11. The method of claim 10, wherein said depositing a bonding material comprises:
depositing the bonding material to form a film on the bond pad.

12. The method of claim 11, further comprising:
singulating the semiconductor die, wherein said depositing the bonding material to form a film is performed prior to said singulating the semiconductor die.

13. The method of claim 11, further comprising:
forming a passivation layer over the semiconductor die to at least partially cover the film, wherein said depositing the bonding material to form a film is performed prior to said forming a passivation layer.

14. The method of claim 10, wherein said depositing a bonding material comprises depositing a spherical gold ball on the bond pad.

15. The method of claim 14, further comprising:
singulating the semiconductor die, wherein said depositing the spherical gold ball is performed subsequent to singulation of the semiconductor die.

16. The method of claim 10, further comprising:
forming a passivation layer on the semiconductor die to cover at least a portion of the bond pad.

17. The apparatus of claim 10, wherein said depositing a bonding material protects the semiconductor die from heat associated with said bonding a wire to the bonding material.

18. A semiconductor package comprising:
a semiconductor die;
a bond pad formed on the semiconductor die, the bond pad comprising aluminum (Al);
a bonding material comprising gold (Au) coupled to the bond pad, the bonding material covering at least a portion of the bond pad;
a wire coupled to the bonding material, the wire comprising copper (Cu); and
a package substrate electrically coupled to the semiconductor die via the wire.

19. The semiconductor package of claim 18, further comprising:
a passivation layer formed on the semiconductor die, the passivation layer being positioned to cover at least a portion of the bond pad.

20. The semiconductor package of claim 18, further comprising:
a mold compound to encapsulate the semiconductor die and the wire.
